(19) United States
(12) Patent Application Publication
(10) Pub. No.: US 2012/0162622 A1
(43) Pub. Date: Jun. 28, 2012

(54) FIELD EXTENSION TO REDUCE NON-YIELDING EXPOSURES OF WAFER

(76) Inventors: Alejandro Varela, Phoneix, AZ (US); Michael A. Maxim, Chandler, AZ (US); Daniel E. Vanlare, Phoenix, AZ (US); Adi Lazar, Gedera (IL)

(21) Appl. No.: 12/977,918

(22) Filed: Dec. 23, 2010

(51) Int. Cl. G03B 27/42; H01L 29/06

(52) U.S. Cl. 355/53; 257/620; 257/E29.006

(57) ABSTRACT

Techniques are provided for efficient lithography processing and wafer layout. In particular, the techniques can be used to reduce the number of sacrificial exposures along the wafer perimeter region. In one example embodiment, an exposure system reticle is configured with both a normal area (die yielding area) and a dumification area (non-yielding area at wafer perimeter), thereby allowing for lithographic processing in the non-yielding areas sufficient to facilitate successful processing in the adjacent die yielding areas, but without requiring additional sacrificial exposures. This reduction in sacrificial exposures translates to a significant improvement in fab capacity. The techniques can be implemented, for example, on any number of lithography tools having an adjustable reticle or reticle blind capability and in the context of any technology nodes, such as 95 nm and smaller. The lithography tool may produce wafers at a faster rate.

### BACKGROUND

Semiconductor wafers, such as silicon, germanium, and III-V material wafers, are used in the fabrication of integrated circuits, where the wafer acts as a substrate upon which microelectronic devices can be formed using various semiconductor processes such as photolithography (e.g., patterning, etching, depositing, etc), epitaxy, doping, polishing, and other such known processes. Typically, a number of identical electronic devices are formed on a single wafer, ranging from tens to hundreds to even thousands of devices per wafer, depending on the size of the device die.

Typically, a lithographic exposure system is used to print electronic devices on a wafer. Such systems generally include a light source (e.g., ultra-violet or deep ultra-violet light), a patterned reticle through which light from the light source can pass, and a lens to focus light passing through the patterned reticle onto a wafer on which the electronic devices are to be formed. Such systems further include a reticle blind, which is typically implemented between the light source and the reticle, for blocking light from reaching portions of the wafer being patterned. This allows portions (fields) of the wafer to be selectively and sequentially printed.

Once formed on the wafer, the devices can be electrically tested and then sorted into passing and non-passing die, using various wafer probing techniques. The wafer can then be singulated into individual die using known techniques such as scribing and breaking, dicing or wire saws, or laser cutting. A perpendicular Cartesian grid is typically used for delineating the individual die, so that during the singulation process the die can be cut in a linear manner across this standard grid. Following the singulation process, the individual die can then be encapsulated into suitable clip packaging, to provide discrete integrated circuits. As would be expected, it is generally desirable to maximize the yield of good die from a given processed wafer.

### BRIEF DESCRIPTION OF THE DRAWINGS

FIG. 1a illustrates yielding and non-yielding die of a wafer, and FIG. 1b illustrates non-yielding field exposures of the wafer.

FIG. 2a is a block diagram of a lithography exposure system configured in accordance with an example embodiment of the present invention.

FIG. 2b is a flow chart demonstrating a controller/processor routine for carrying out lithography processing in accordance with an embodiment of the present invention.

FIGS. 3a-3e each illustrate a set of reticle blinds configured to manipulate the size of exposure fields to create a dumification area within a given field, in accordance with an example embodiment of the present invention.

FIG. 4a illustrates a wafer layout comprising a Cartesian grid of fields, as commonly done.

FIG. 4b illustrates the same example wafer layout of FIG. 4a, but employs field extension techniques to reduce the number of zero yielding exposures, in accordance with an embodiment of the present invention.

FIG. 5 shows an expanded view of a wafer printed with multiple die sizes to more optimally utilize wafer space, in accordance with an embodiment of the present invention.

### DETAILED DESCRIPTION

Techniques are provided for efficient lithography processing and wafer layout. In particular, the techniques can be used to reduce the number of sacrificial exposures along the wafer perimeter region. In one example embodiment, an exposure system reticle is configured with both a normal area (die yielding area) and a dumification area (non-yielding area at wafer perimeter), thereby allowing for lithographic processing in the non-yielding areas sufficient to facilitate successful processing in the adjacent die yielding areas, but without requiring additional sacrificial exposures. This reduction in sacrificial exposures translates to a significant improvement in fab capacity. The techniques can be implemented, for example, on any number of lithography tools having an adjustable reticle or reticle blind capability and in the context of any technology nodes, such as 95 nm and smaller. The lithography tool may produce wafers at a faster rate.

General Overview

As previously explained, identical integrated circuit die fabricated on a wafer are normally singulated in a linear manner across a standard perpendicular grid. Thousands of wafers can be fabricated in the same manner, to produce hundreds of thousands of individual die. However, when each wafer is printed, a portion of each wafer along the outer diameter edge may be non-yielding. In particular, partial and sometimes even full die may be printed in this area in order to sustain uniform manufacturing operations, but the full die within this edge exclusion zone normally do not yield and the partial die are discarded as unusable during the dicing operation.

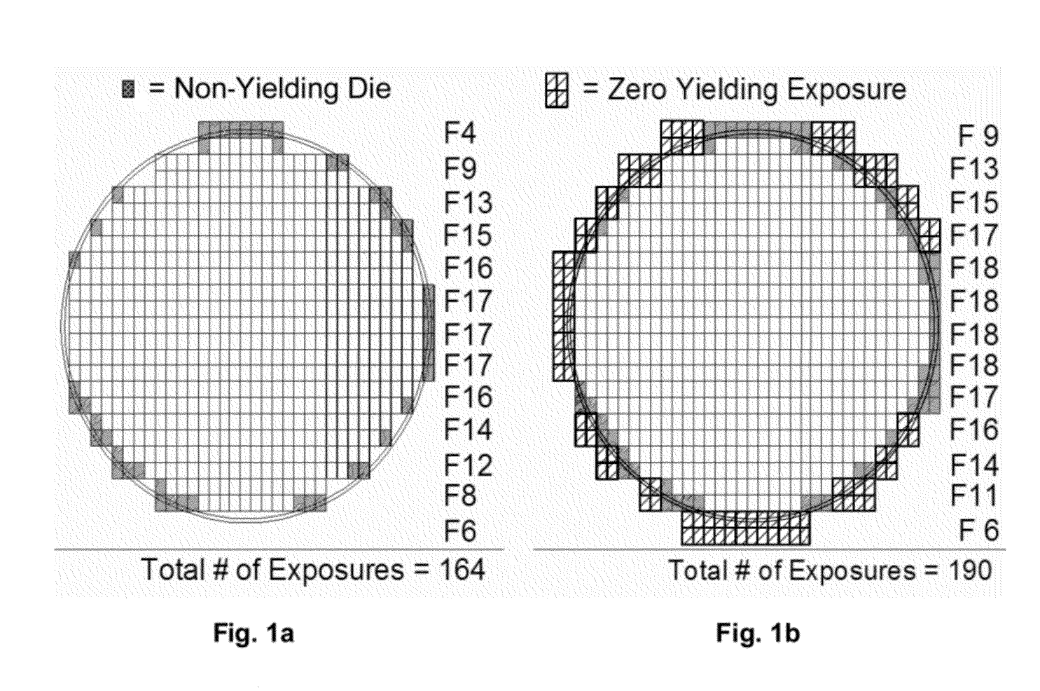

In more detail, and with reference to FIGS. 1a and 1b, a typical conventional process flow selectively prints the edge exposure fields even when those fields produce no yielding die, for the benefit of proximity/edge sensitive die (typically metal layers). FIG. 1a shows a wafer having a grid pattern indicated thereon, wherein each square of the grid may represent a die area. As can be seen in FIG. 1a, the shaded die areas that fall on the edge/perimeter of the wafer are non-yielding. As can be further seen in this example, the field is a 2-by-2 die array, and the number of fields that yield one or more die is indicated to the right of each corresponding field row. A total of 164 field exposures that contain one or more yielding die are provided in this example.

As can be seen with reference to FIG. 1b, in addition to these 164 die yielding field exposures, there are an additional 26 zero yielding field exposures that are printed. These 26 additional field exposures are sacrificial in that they themselves will not yield any usable die; however, they effectively allow the various adjacent die yielding field exposures to yield. This necessary process of providing sacrificial exposures can be referred to as dumification. Such dumification can represent a significant waste of lithography resources (e.g., processing time, consumables, lens degradation). In the example process/wafer shown in FIGS. 1a-b, approximately 14% of the metal exposures are wasted due to this dumification process requirement.

The techniques provided herein allow for wafer edge dumification without requiring extra patterning exposures, or otherwise allows for a reduction in the number of dumification exposures. Depending on factors such as the field size and wafer size, this reduction can be, for instance, 10% or higher which translates into improved fab capacity. In one example case, a 10% reduction in dumification exposures translates to roughly a 3% to 5% improvement in capacity for all fab processes. This is a non-trivial improvement, particularly when considered in the context of high volume fabs.

As will be appreciated, the field size can be defined by the reticle pattern and position of the reticle blinds of the exposure system. In one example embodiment, a field size of 25 mm×33 mm is typical and can be used, for example, in processing technology nodes of 95 nm and smaller. A field may be configured to provide one or more die, depending on the size of the field and the individual die. Fields having a 2×2 or 2×3 die array are typical example configurations. Note, however, that the field size and die array configuration can vary from one process to the next, and the claimed invention is not intended to be limited to any particular size range or die array configuration.

In any such cases, and in accordance with an example embodiment of the present invention, the reticle blinds of the exposure system can be manipulated to move and/or change the size of the exposure fields to create the dumification area within the field (i.e., in addition to the normal area of the field). In another embodiment, the reticle blind itself is adjustable so as to allow for changing the size of the exposure field to include both the dumification (non-yielding) and normal (yielding) areas. In some such cases, a dumification pattern can be added in the unused space of the exposure field and used to produce the dumification on the edge of the wafer (e.g., so as to address edge proximity/edge sensitive die issues, if any). The dumification area can thus be printed at the same time that adjacent good yielding die are printed, if so desired.

In contrast, conventional processes require an entire lithography exposure to be printed on the edge of the wafer to produce the additional sacrificial exposures of the dumification area that are used to effectively trick the adjacent good die to behave in a manner that allows them to yield. The amount of resources to print an exposure is relatively constant. As such, reducing the number of necessary lithography exposures translates, for instance, into faster tool speeds, reduced laser consumables, and reduced lens degradation. Thus, various embodiments of the present invention allow lithography tools to produce more products at a lower cost given that the number of lithography exposures required per wafer per affected layer would be reduced.

As will be appreciated in light of this disclosure, there are a number of benefits that can be realized using embodiments of the present invention. As previously explained, lithography tool processing time can be reduced based on sacrificial exposures that are eliminated. Note, however, that in some embodiments, depending on the tool configuration, processing time may be added as well. For example, some tools may be programmed or otherwise configured to do an alignment re-calculation every time the reticle blinds of the tool are re-positioned or the reticle itself is adjusted. As will be appreciated in light of this disclosure, such automatic alignment procedures are not necessary, and can be deactivated to benefit from reduced process times.

The techniques can be embodied, for example, in semiconductor processing equipment configured for executing lithography field layout and subsequent printing (device formation) within those fields. The actual type of devices being formed on the wafer is not particularly relevant. Example devices being formed may be, for instance, processors, memory devices, transistors, or logic circuits. Numerous other microelectronic devices that can be formed on a wafer will be apparent, whether the device is a discrete component or a circuit including many components. The disclosed methodologies are suitable for practice at fabs where microelectronics are made on a large scale production basis, or even in smaller scale production environments (e.g., custom built silicon). In short, the field extension techniques provided herein can be used to reduce the number of sacrificial (i.e., non-yielding) field exposures in any production environment.

Thus, current solutions for lithography field layout do not optimally utilize the tool configuration capabilities, thereby necessitating non-yielding field exposure processing in the dumification area of wafers. This results in wasted materials, additional wear-and-tear on equipment, and reduced fab capacity. The techniques provided herein can be used to optimize dumification area processing thereby reducing wafer processing times, materials used, and equipment.

Lithography Exposure System with Field Extension Capability

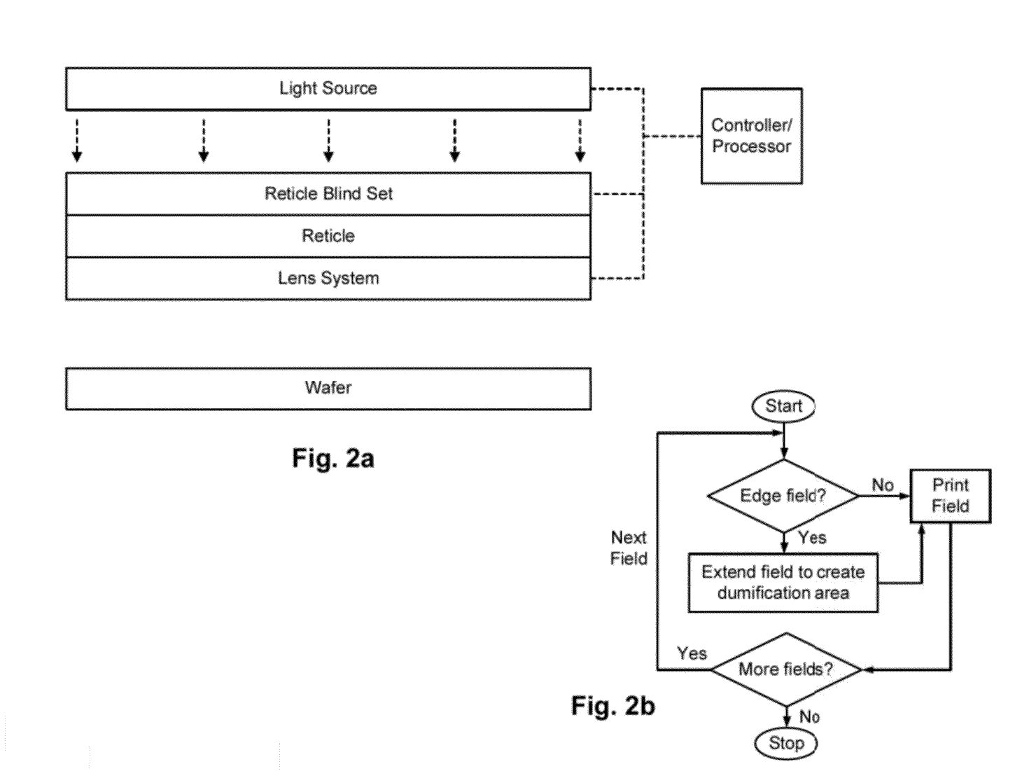

FIG. 2a is a block diagram of a lithography exposure system configured in accordance with an example embodiment of the present invention. As can be seen, the system generally includes light source, a reticle blind set and corresponding reticle, and a lens systems. Each of the light source, reticle blind set, and lens system is responsive to a controller/processor. In other embodiments, note that the reticle blind set may be integrated directly into the reticle. In such cases, the reticle may be responsive to the controller/processor. In any such cases, the system can be operated to pattern an underlying wafer with desired circuitry. Other typical components of a lithography exposure system are not shown, but will be apparent (such as vacuum wafer chuck, vacuum/process chamber, processing fixtures for gas delivery, etc).

The light source can be any type of light source that is suitable for printing a wafer (e.g., such as a ultra-violet or deep ultra-violet light source or extreme ultra-violet). The reticle may be configured as conventionally done, and may include, for instance, a sheet of glass coated with an opaque patterned material (e.g., chrome) on its backside. The pattern can correspond to any number of circuit architectures. The lens system focuses light from the light source onto the underlying wafer. The reticle blind set may include one or more reticle blinds. In one example embodiment, the set include top and bottom reticle blinds along with left and right reticle blinds. Each reticle blind is movable in response to control signals from the controller/processor, and can be implemented, for example, with an opaque plate such as a metal plate (e.g., aluminum or chrome) or a glass plate coated with a metal (e.g., chrome). Any number of reticle blind configurations can be used here, so long as the blinds are capable of blocking the light from the light source and can be manipulated to provide field extensions as described herein.

The controller/processor can be configured to control the lithography exposure system as commonly done and/or in response to user input, and may execute any number of conventional lithography processes and common manipulations of the system. In addition, the controller/processor can be programmed or otherwise configured to manipulate the reticle blinds (or the reticle itself, if the blinds are integral therein) so as to provide field extensions as needed when the system is processing fields at the wafer perimeter, in accordance with an embodiment of the present invention. The controller/processor can be implemented, for example, with a computer (e.g., desktop, laptop, or other suitable computing device) programmed or otherwise configured to carryout control of the system, including moving and/or changing the size of the exposure fields to create the dumification area within the field as described herein. Alternatively, the controller/processor can be implemented with a microcontroller having I/O capability and a number of executable routines encoded therein for carrying out system control, including moving and/or changing the size of the exposure fields to create the dumification area within the field as described herein. Any number of suitable control/processing schemes will be apparent in light of this disclosure and can be used as well. FIG. 2 be illustrates one example routine that can be executed or otherwise carried out by the controller/processor.

The wafer can be implemented, for example, with any number of suitable semiconductor materials, such as silicon, germanium, or III-V materials, and may be in bulk form or in a semiconductor on insulator configuration such as silicon on insulator (SOD or silicon germanium on insulator (SiGeOI). The top surface of the substrate may be strained or not. Any number of suitable wafer configurations can be used here, depending on factors such as the devices being formed and the desired material systems, as will be appreciated. In any case, the wafer generally comprises a number of exposure field areas, each including one or more die areas, with at least some of the field areas in the perimeter region of the wafer being partial or otherwise incomplete.

FIG. 2b illustrates an example controller/processor routine for carrying out lithography processing in accordance with an embodiment of the present invention. The routine may be implemented, for example, using software (e.g., C or C++ executing on the controller/processor), hardware (e.g., hardcoded gate level logic or purpose-built silicon) or firmware (e.g., embedded routines executing on a microcontroller). As can be seen, the process generally includes printing fields on a wafer as typically done, which may include any number of conventional processes.

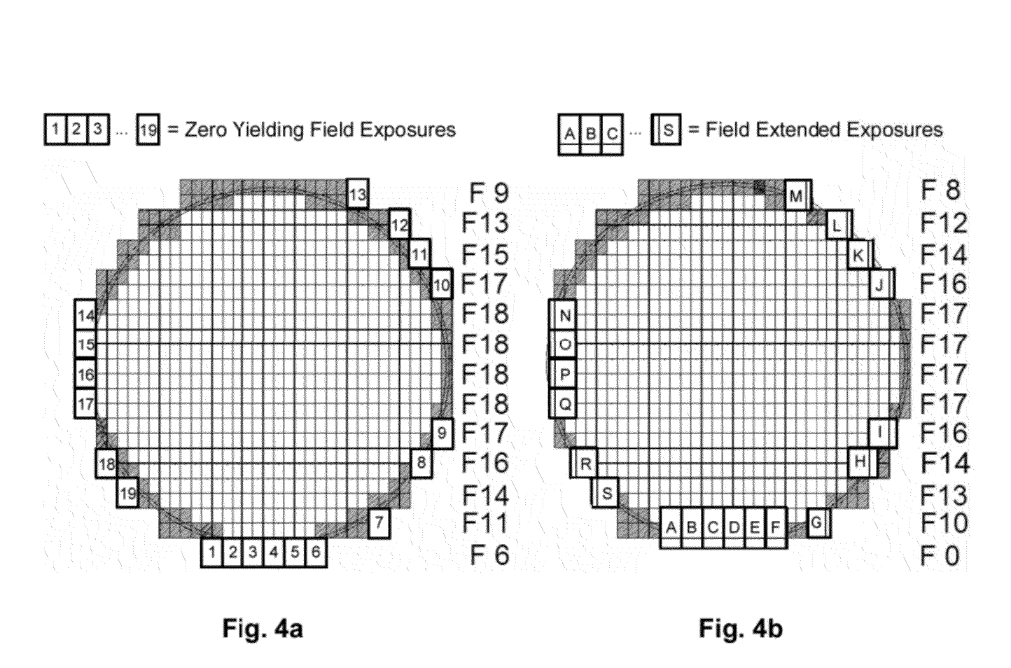

However, an additional aspect of the routine is that it makes a determination as to whether the field being processed is an edge field or not. This can be achieved, for example, based on a known wafer layout where each of the edge fields of the wafer is identified and recorded in a data file accessible to the routine. One such example wafer layout is shown in FIG. 4b (which shows edge fields A through S), and will be discussed in turn. As the fields are systematically processed, each field can be checked against the data file to see if it is an edge field or not. If not an edge field, then the field can be printed as conventionally done, as shown.

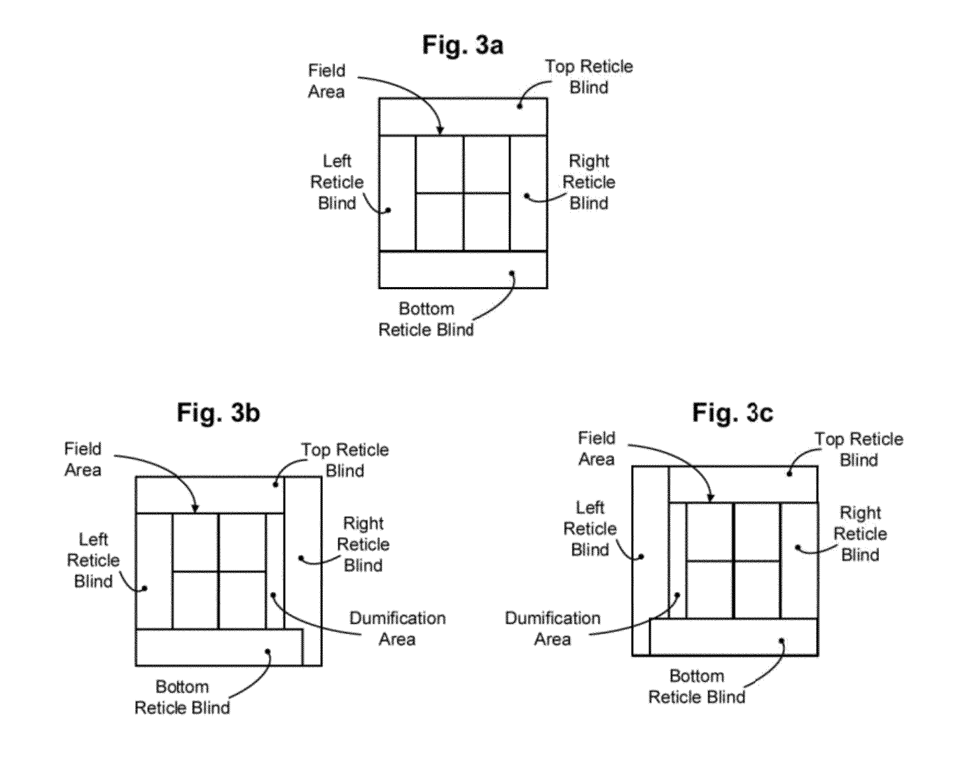

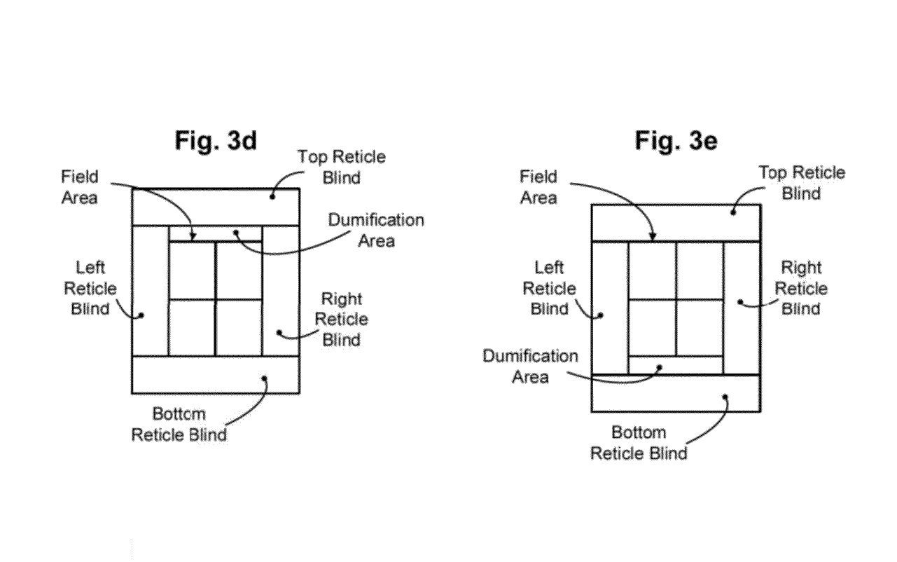

If, however, the field is an edge field, then the routine continues with extending the field size to create a dumification area. In one example such embodiment, a data file that identifies each of the edge fields further indicates whether that edge field is a top expanding field, a bottom expanding field, a right expanding field, and/or a left expanding field. This allows the controller/processor to, for example, signal the appropriate reticle blinds to move in the appropriate direction to provide the field extension in the desired direction. A number of example reticle blind configurations for providing dumification areas are discussed in turn with reference to FIGS. 3a-3e.

In either case, the normal edge field or the extended edge field is then printed. Conventional lithography techniques can be used here, as will be appreciated. The dumification area may include a pattern that is compatible or otherwise facilitates proper printing of the field exposure being simultaneously printed. Once all the fields of the wafer have been systematically processed, the routine terminates. Any number of implementations for identifying edge fields and the desired reticle blind movement can be used here, as will be apparent in light of this disclosure.

Field Exposure Manipulation

FIGS. 3a-3e each illustrate a set of reticle blinds configured to manipulate the size of exposure fields to create a dumification area within a given field, in accordance with an example embodiment of the present invention. As can be seen in this example embodiment, the field includes a 2-by-2 die array, although any number of other die configurations can be used here as well.

In this example configuration, the field is generally bounded by a set of four individual reticle blinds, including top, bottom, left and right blinds, and each can move independently of the other blinds (e.g., in response to control from the controller/processor). The reticle blinds can be positioned over the field to prevent light from the light source from passing to the underlying wafer being patterned. Numerous blind configurations will be apparent in light of this disclosure. For instance, another embodiment may have three fixed reticle blinds and a single movable reticle blind configured to expand one side of the field, assuming such limited field expansion is acceptable for a given application. Alternatively, the set of reticle blinds can be implemented with a single reticle frame structure that can rotate or otherwise be selectively positioned over the field so as to provide a field extension on any given field side or perimeter area, depending upon which wafer edge is be printed at that time. Further note that, while this example embodiment shows top and bottom reticles at 90 degree angles with respect to left and right reticles to accommodate a rectangular or square field shape, other embodiments may employ one or more reticles at non-right angles, such as 45 and/or 60 degrees, to accommodate a corresponding field shape or as otherwise desired. In some such cases, note that the field may include a non-straight perimeter (curved) and the blinds can be shaped to complement that perimeter shape. In short, the reticle blind configuration can vary greatly, and the claimed invention is not intended to be limited to any particular number of blinds or blind configuration.

FIG. 3a shows the reticle blinds in a non-expanded configuration, in accordance with one example embodiment. This mode can be used, for example, when carrying out field exposures in the non-perimeter areas of the wafer. FIG. 3b shows the reticle blinds in a right-expanded configuration, in accordance with one example embodiment. As can be seen, the right blind has moved outward to effectively expand the right side of the field to provide a dumification area. FIG. 3c shows the reticle blinds in a left-expanded configuration, in accordance with one example embodiment. Here, the left blind has moved outward to effectively expand the left side of the field to provide a dumification area. FIG. 3d shows the reticle blinds in a top-expanded configuration, in accordance with one example embodiment. Here, the top blind has moved upward to effectively expand the top side of the field to provide a dumification area. FIG. 3e shows the reticle blinds in a bottom-expanded configuration, in accordance with one example embodiment. Here, the bottom blind has moved downward to effectively expand the bottom side of the field to provide a dumification area. The width of the dumification area (which corresponds to the distance the blind is moved) can be set as desired, to accommodate the specific layout of a given wafer. In any case, the dumification area can be printed at the same time as the normal field area. The dumification area generally corresponds to a zero-yielding die area at and/or over the wafer edge, as will be appreciated in light of this disclosure.

Note that in some embodiments, the reticle blinds can be configured to provide a complex field extension, such as a double-sided field extension. For example, the top reticle blind can be moved upward and the right reticle blind can be moved outward, thereby providing an L-shaped field extension. Such a field extension may be appropriate, for instance, in an upper right corner/perimeter area of a wafer. There may be other instances, for whatever reason, where an internal dumification area is desired. In such cases, any or all the blinds can be moved or otherwise manipulated to provide the desired field extension shape. Numerous such configurations will be apparent in light of this disclosure.

FIG. 4a illustrates an example wafer layout comprising a Cartesian grid of fields, as commonly done. Each field in this example case includes a 2-by-2 die array. A typical lithography system will carryout the field exposure process on the wafer in a systematic fashion (e.g., row by row, from right to left side of wafer, and from bottom to top of wafer). The total number of field exposures per row for this example case is shown to the right of each row (e.g., F9=nine field exposure for that row, etc). In addition, some (but not necessarily all) of the zero yielding field exposures of this total exposure set are numbered 1 through 19. With a conventional lithography process, these 19 full field exposures will be carried out, despite the fact that none of them will likely yield.

FIG. 4b illustrates the same example wafer layout, but employs the field extension techniques described herein to reduce the number of zero yielding exposures, in accordance with an embodiment of the present invention. As can be seen, each of the 19 zero yielding field exposures shown in FIG. 4a are eliminated by using an appropriately extended field. For instance, each of fields A through F shown in FIG. 4b is expanded downward (e.g., using the bottom reticle blind as shown in FIG. 3e) so as to allow the dumification area under those fields to be simultaneously printed with the above yielding field exposures. In a similar fashion, each of fields G through M shown in FIG. 4b is expanded to the right (e.g., using the right reticle blind as shown in FIG. 3b) so as to allow the dumification area to the right of those fields to be simultaneously printed with the yielding field exposures to the left. Likewise, each of fields N through S shown in FIG. 4b is expanded to the left (e.g., using the left reticle blind as shown in FIG. 3c) so as to allow the dumification area to the left of those fields to be simultaneously printed with the yielding field exposures to the right. The pattern in the dumification area can be configured so as to facilitate successful printing of the yielding fields, as previously explained. In one example case, the pattern is the same as the normal field pattern, or otherwise has substantially the same density (e.g., the same geometric amount of open and closed spaces). Alternatively, the dumification pattern can allow for metallization of the dumification area. In other embodiments, there is no dumification pattern, so long as the field exposure yields as desired. As will be appreciated in light of this disclosure, the dumification pattern can be used, for example, to prevent the edge of a good die from being corrupted by subsequent processing (e.g., etching or other deleterious step), and/or otherwise inhibits processing fluids and aids from undesirably interacting with sensitive perimeter regions of yielding die.

Multiple Die Size Wafer Layouts

One further embodiment of the present invention enables more efficient use of wasted space at the wafer edge, to increase yield from a given wafer. This technique can be used in conjunction with dumification as described herein, but need not be as will be appreciated in light of this disclosure. In more detail, it is typical that a given wafer layout includes a single die type, with each die being the same size and shape. Once fields of these die are patterned on a wafer, the perimeter of that wafer generally includes unpatterned or otherwise wasted space. Specifically, between 3% to 18% of the edge of the wafer is typically wasted (mostly a result of printing square die on a round wafer). Thus, to more efficiently utilize that wasted space, one embodiment of the present invention mixes two or more die types of varying size on the same wafer.

For example, a large primary die can be efficiently printed on the more central wafer portion and out towards the wafer perimeter. While the remaining unprinted wafer space may not be able to accommodate additional field exposures of the large die, a number of a second smaller die types can be printed there. In one such specific embodiment, the two die selected for printing on wafer share the same routing, thereby facilitating printing of both die types. However, if routing is different for the married die, then the technique can still be employed, but process adjustments may be necessary to switch from printing one die type to another. This technique can be used to many any number of large-small die combinations to facilitate their printing on a wafer.

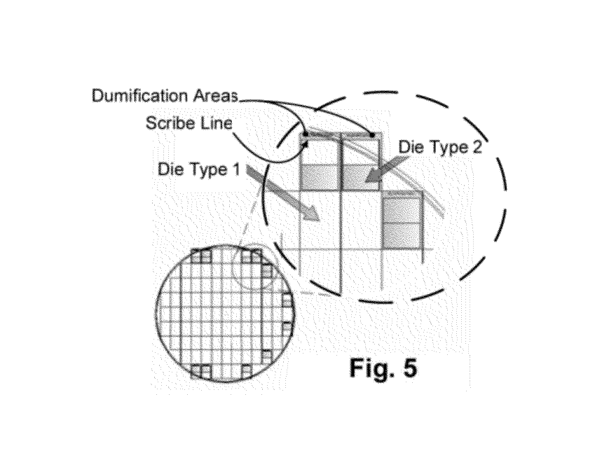

In one such embodiment, reticles for the smaller die can be designed to include a scribe line of the larger die, and the unused area between the two field scribe lines can be dumified as described herein. The larger die reticles can be implemented as conventionally done. One such example embodiment is demonstrated in FIG. 5, which shows an expanded view of a wafer printed with multiple die sizes to more optimally utilize wafer edge space. As can be seen, the larger die type 1 is printed in the central section of the wafer, and the smaller die type 2 is printed along the wafer edge. Note how the field corresponding to the larger die type 1 would be non-yielding in the three high-lighted locations of the expanded view, yet four of the smaller die type 2 can be accommodated. In this example case, the reticle for the smaller die type 2 includes a scribe line of the larger field, thereby allowing a dumification area to be defined along with the two type 2 die within that field. Note that, in some embodiments, the reticle blinds can be adjusted to modify the dumification area size as desired (to print less or more of the dumification pattern) as described herein.

Still in another embodiment, and as previously indicated, note that a multi-die configuration as described herein can be implemented without dumification. For example, one such embodiment would be similar to that shown in FIG. 5, except the two dumification areas would not be printed or otherwise allocated in the large frame. Alternatively, a conventional sacrificial field could be printed, if so desired.

Numerous embodiments and configurations will be apparent in light of this disclosure. For instance, one example embodiment of the present invention provides a semiconductor wafer. In one such embodiment, the wafer includes a grid of rows and columns of fields, wherein at least one field is extended in size relative to other fields to include a dumification area proximate to an edge of the wafer. As will be appreciated in light of this disclosure, the dumification area may not be present on the wafer, or only partially present, in that it is sacrificial in nature (where some of the dumification area is printed off-wafer). In this sense, the dumification area as claimed may be partial or otherwise only include telltale indications of an extended field including dumification as described herein. The wafer may further include a plurality of die formed on the wafer, each field including one or more of the die. In one such example case, the fields are rectangular in shape. In another example case, the wafer only has one die type formed thereon, and each die is the same size. In another example case, the wafer has a first die type and a second die type formed thereon, and the first die type is larger than the second die type. In one such case, each of the second die type is printed proximate to an edge of the wafer and is associated with a field that includes a dumification area. In another example case, the wafer is associated with a smaller number of zero yielding fields relative to a second wafer identical to the wafer in wafer size and field size, but having no extended fields that include a dumification area proximate to an edge of the second wafer. In another example case, the wafer can be, for instance, a bulk wafer or a semiconductor on insulator configuration.

Another example embodiment of the present invention provides a non-transient processor readable medium encoded with instructions that, when executed by a processor, causes a lithography process to be carried out. The process in one such example case includes determining if a field being processed on a semiconductor wafer and having a size is proximate an edge of the wafer. The process further includes extending the field size to create a dumification area within the field, if the field is proximate an edge of the wafer. In one example such case, the process further includes printing a die associated with the field on a wafer. In another example case, if the field is proximate an edge of the wafer, the process further includes simultaneously printing the dumification area and a die associated with the field. In another example case, extending the field size to create a dumification area within the field includes signaling at least one reticle blind to move thereby extending the field size. In another particular case, the fields are rectangular in shape. In another particular case, each field includes one or more die, and each die is the same size. In another particular case, each field includes one or more die, and die associated with at least one of the fields proximate to an edge of the wafer are smaller than die associated with fields not proximate to an edge of the wafer. In one such case, at least one of the smaller die printed proximate to an edge of the wafer is associated with a field that includes dumification area. In another particular case, the process produces a wafer that is associated with a smaller number of zero yielding fields relative to a second wafer identical to the wafer in wafer size and field size, but having no extended fields that include a dumification area proximate to an edge of the second wafer. Note that the processor readable medium can be any suitable storage device such as, for example, a compact disk, hard drive, read only memory (ROM), USB drive or other portable memory device, server, or memory of a lithography system.

Another embodiment of the present invention provides a lithography system. The system includes, for example, a light source, a reticle having a pattern and for printing field exposures on a semiconductor wafer, a reticle blind for selectively blocking light from the light source from passing through the reticle, and a controller configured to determine if a field being processed on the wafer and having a size is proximate an edge of the wafer, and if the field is proximate an edge of the wafer, extend the field size to create a dumification area within the field. In one such case, the controller is further configured to cause printing a die associated with the field on a wafer. In another such case, if the field is proximate an edge of the wafer, the controller is further configured to cause simultaneous printing of the dumification area and a die associated with the field. In another such case, the controller is configured to extend the field size to create a dumification area within the field by signaling at least one reticle blind to move thereby extending the field size.

The foregoing description of example embodiments of the invention has been presented for the purposes of illustration and description. It is not intended to be exhaustive or to limit the invention to the precise forms disclosed. Many modifications and variations are possible in light of this disclosure. For instance, note that field and die shapes are not limited to square or rectangular shapes. Rather, they can have any geometric shape (e.g., triangle, circle, or irregular shape). Likewise, processing details such as wavelength of light, technology node, and feature sizes can vary widely. In short, various embodiments of the present invention can be implemented to operate with all such geometric shapes and processing details. It is intended that the scope of the invention be limited not by this detailed description, but rather by the claims appended hereto.

What is claimed is:

1. A semiconductor wafer, comprising:
a grid of rows and columns of fields, wherein at least one field is extended in size relative to other fields to include a dumification area proximate to an edge of the wafer; and
a plurality of die formed on the wafer, each field including one or more of the die.

2. The semiconductor wafer of claim 1 wherein the fields are rectangular in shape.

3. The semiconductor wafer of claim 1 wherein the wafer only has one die type formed thereon, and each die is the same size.

4. The semiconductor wafer of claim 1 wherein the wafer has a first die type and a second die type formed thereon, and the first die type is larger than the second die type.

5. The semiconductor wafer of claim 4 wherein each of the second die type is printed proximate to an edge of the wafer and is associated with a field that includes a dumification area.

6. The semiconductor wafer of claim 1 wherein the wafer is associated with a smaller number of zero yielding fields relative to a second wafer identical to the wafer in wafer size and field size, but having no extended fields that include a dumification area proximate to an edge of the second wafer.

7. The semiconductor wafer of claim 1 wherein the wafer is a bulk wafer or a semiconductor on insulator configuration.

8. A non-transient processor readable medium encoded with instructions that, when executed by a processor, causes a lithography process to be carried out, the process comprising:
determining if a field being processed on a semiconductor wafer and having a size is proximate an edge of the wafer; and
if the field is proximate an edge of the wafer, extending the field size to create a dumification area within the field.

9. The medium of claim 8 wherein the process further comprises printing a die associated with the field on a wafer.

10. The medium of claim 8 wherein if the field is proximate an edge of the wafer, the process further comprises simultaneously printing the dumification area and a die associated with the field.

11. The medium of claim 8 wherein extending the field size to create a dumification area within the field comprises signaling at least one reticle blind to move thereby extending the field size.

12. The medium of claim 8 wherein the fields are rectangular in shape.

13. The medium of claim 8 wherein each field includes one or more die, and each die is the same size.

14. The medium of claim 8 wherein each field includes one or more die, and die associated with at least one of the fields proximate to an edge of the wafer are smaller than die associated with fields not proximate to an edge of the wafer.

15. The medium of claim 14 wherein at least one smaller die printed proximate to an edge of the wafer is associated with a field that includes a dumification area.

16. The medium of claim 8 wherein the process produces a wafer that is associated with a smaller number of zero yielding fields relative to a second wafer identical to the wafer in wafer size and field size, but having no extended fields that include a dumification area proximate to an edge of the second wafer.

17. A lithography system, comprising:
a light source;
a reticle having a pattern and for printing field exposures on a semiconductor wafer;
a reticle blind for selectively blocking light from the light source from passing through the reticle; and
a controller configured to determine if a field being processed on the wafer and having a size is proximate an edge of the wafer, and if the field is proximate an edge of the wafer, extend the field size to create a dumification area within the field.

18. The system of claim 17 wherein the controller is further configured to cause printing a die associated with the field on a wafer.

19. The system of claim 17 wherein if the field is proximate an edge of the wafer, the controller is further configured to cause simultaneous printing of the dumification area and a die associated with the field.

20. The system of claim 17 wherein the controller extends the field size to create a dumification area within the field by signaling at least one reticle blind to move thereby extending the field size.
